(19) United States
(12) Patent Application Publication
(10) Pub. No.: US 2011/0097832 A1
(43) Pub. Date: Apr. 28, 2011

(54) METHOD FOR FABRICATING LED DEVICE

(75) Inventors: Ben FAN, He Shan City (CN); Hsin-Chuan Weng, He Shan City (CN); Kuo-Kuang Yeh, He Shan City (CN)

(73) Assignee: He Shan Lide Electronic Enterprise Company Ltd., He Shan City (CN)

(21) Appl. No.: 12/984,800

(22) Filed: Jan. 5, 2011

Related U.S. Application Data
(62) Division of application No. 12/354,281, filed on Jan. 15, 2009.

(30) Foreign Application Priority Data
Mar. 13, 2008 (CN) 200810026797.7

(51) Int. Cl. H01L 33/38

(52) U.S. Cl. 438/29; 257/E33.074

(57) ABSTRACT

An LED device has a substrate, an N-type semiconductor layer formed on the substrate, a light-emitting layer on the N-type semiconductor layer, a P-type semiconductor layer on the light-emitting layer and a transparent electrode layer formed on the P-type semiconductor layer. A top surface of the transparent electrode layer is formed to have multiple micro concave-convex structures to mitigate the light-emitting loss resulted from total reflection, and increase the light-emitting efficiency of the LED device.

### CROSS REFERENCE

The present invention is a divisional application claiming the benefit of U.S. patent application Ser. No. 12/354,281 filed on Jan. 15, 2009.

### BACKGROUND OF THE INVENTION

1. Field of the Invention

The invention relates to a method for fabricating the LED device, and more particularly to an LED device with increased light-emitting efficiency by roughening a surface of a transparent electrode layer.

2. Description of Related Art

A light emitting diode (LED) is a diode with a P-N junction manufactured by semiconductor material. When a forward current is applied to the P-N junction, the unbalanced carriers injected to the LED, i.e. the electrons and holes will meet together to generate light during the diffusion processes of the carriers. The semiconductor material of LED is heavy-doped material with many high-mobility electrons in the N region and low-mobility holes in the P region under a thermal-balanced status. The electrons cannot naturally combine with the holes in a normal status because the P-N junction acts as a barrier and blocks the carriers. When a forward voltage is applied to the P-N junction, the conduction band electrons from the N region can pass through the P-N junction barrier and enters the P region. Therefore, when an electron from the high energy level meet a hole in the P region near the P-N junction, the electron releases energy in the form of a photon.

A conventional method for manufacturing an LED device is to sequentially form an N-type semiconductor material, a ligh-emitting layer and a P-type semiconductor material. To produce different light wavelengths, the LEDs uses different semiconductor material and has different structures. Taking the blue and green light LED as an example, sapphire material is used to form a substrate and indium gallium nitride (InGaN) is used in the light-emitting layer. Because the sapphire substrate is an isolation substrate, the cathode and anode of the LED are all created on the top surface of the LED structure. With reference to FIGS. 1 and 2, a N-type gallium nitride (GaN) layer (5), a light-emitting layer (4), a P-type GaN layer (3) and a transparent electrode layer (2) are sequentially formed on a sapphire substrate (6). A cathode (1) and an anode (7) of the LED are respectively formed on the transparent electrode layer (2) and the GaN layer (5). When the light generated from the light-emitting layer (4) emits outwardly, the light sequentially passes through the P-type GaN layer (3), the transparent layer (2) and a packaging resin layer (not shown) encapsulated on the transparent layer (2) to outer space. The refractive indexes of P-type GaN layer (3), the transparent electrode layer (2) and the packaging resin layer are about 2.4, 1.85-2.0 and 1.45-1.55 respectively. When the light transmits from high refractive index material to the low refractive material, a total-reflection may easily occur at the junction of the high refractive index material and the low refractive material, and causes the LED device emitting a low intensity light to outer space. The light-emitting efficiency of the blue and green LED is relative low.

### SUMMARY OF THE INVENTION

The main objective of the present invention is to provide an LED device with high light-emitting efficiency.

In accordance with one aspect of the present invention, an LED device has a substrate, an N-type semiconductor layer formed on the substrate, a light-emitting layer on the N-type semiconductor layer, a P-type semiconductor layer on the light-emitting layer, a transparent electrode layer formed on the P-type semiconductor layer, an anode formed on the transparent electrode layer and a cathode formed on the N-type semiconductor substrate, wherein the transparent electrode layer has a top surface on which micro concave-convex structures are formed.

Preferably, the transparent electrode layer has a bottom surface on which multiple concave-convex structures are formed.

Preferably, the transparent electrode layer has a thickness range from 0.2 to 0.8 micrometers.

In accordance with another aspect of the present invention, an LED device has a substrate, an N-type semiconductor layer formed on the substrate, a light-emitting layer on the N-type semiconductor layer, a P-type semiconductor layer on the light-emitting layer, a transparent electrode layer formed on the P-type semiconductor layer, an anode formed on the transparent electrode layer and a cathode formed on the N-type semiconductor substrate, wherein multiple holes extending from the transparent electrode layer to the N-type semiconductor substrate are formed.

Preferably, a pitch between two adjacent holes is 2 to 8 micrometers, and each hole has a thickness of 1 to 2 micrometers and a diameter of 0.2 to 4 micrometers.

In accordance with yet another aspect of the present invention, a method for manufacturing LED device has the steps of

sequentially depositing an N-type semiconductor layer, a light-emitting layer and a P-type semiconductor layer on a substrate;

forming a transparent electrode layer on the P-type semiconductor layer;

pattering and etching parts of the transparent electrode layer, the P-type semiconductor layer, the light-emitting layer and the N-type semiconductor layer with an photolithography process; and

wet etching the transparent electrode layer with roughening etchant to form multiple micro concave-convex structures on the transparent electrode layer.

Preferably, the roughening etchant is an acid solution composed of sulfuric acid, inhibitor, surfactant and deionized water.

Preferably, a dry or wet etching process is applied to a top surface of the P-type semiconductor layer before forming the transparent electrode layer on the P-type semiconductor layer to form multiple micro concave-convex structures on the top surface of the P-type semiconductor layer.

In accordance with yet another aspect of the present invention, a method for manufacturing LED device has the steps of

sequentially depositing an N-type semiconductor layer, a light-emitting layer and a P-type semiconductor layer on a substrate;

forming a transparent electrode layer on the P-type semiconductor layer;

coating a photoresist layer on the transparent electrode layer and pattering the transparent electrode layer with photolithography processes to define patterns of multiple holes;

using the photoresist layer as a protection layer and etching parts of the transparent electrode layer, the P-type semiconductor layer, the light-emitting layer and the N-type semiconductor layer with a dry etching process to form the multiple holes that extend from the transparent electrode layer to the N-type semiconductor layer; and

removing the photoresist layer from the transparent electrode layer.

Preferably, the dry etching process is an inductively coupled reactive ion etching process.

Preferably, the multiple holes have a pitch of 2 to 8 micrometers, and each of the multiple holes has a depth of 1 to 2 micrometers and a diameter of 0.2 to 4 micrometers.

Other objectives, advantages and novel features of the invention will become more apparent from the following detailed description when taken in conjunction with the accompanying drawings.

### BRIEF DESCRIPTION OF THE DRAWINGS

FIG. 1 is a plan schematic view of a conventional blue and green light LED device;

FIG. 2 is a cross section view of the conventional blue and green light LED device of FIG. 1 taken from the line 2-2 in FIG. 1;

FIG. 3 is a plan schematic view of a first embodiment of an LED device in accordance with the present invention;

FIG. 4 is a cross section view of the LED device of FIG. 3 taken from the line 4-4 in FIG. 1;

FIGS. 5A to 5C show manufacturing processes of the first embodiment of an LED device in accordance with the present invention;

FIG. 6 is a cross section view of a second embodiment of the LED device in accordance with the present invention;

FIG. 7 is an enlarged cross section view of micro concave-convex structures shown in FIG. 6;

FIGS. 8A to 8C show manufacturing processes of the second embodiment of the LED device in accordance with the present invention; and

FIG. 9 is a cross section view of a third embodiment of the LED device in accordance with the present invention.

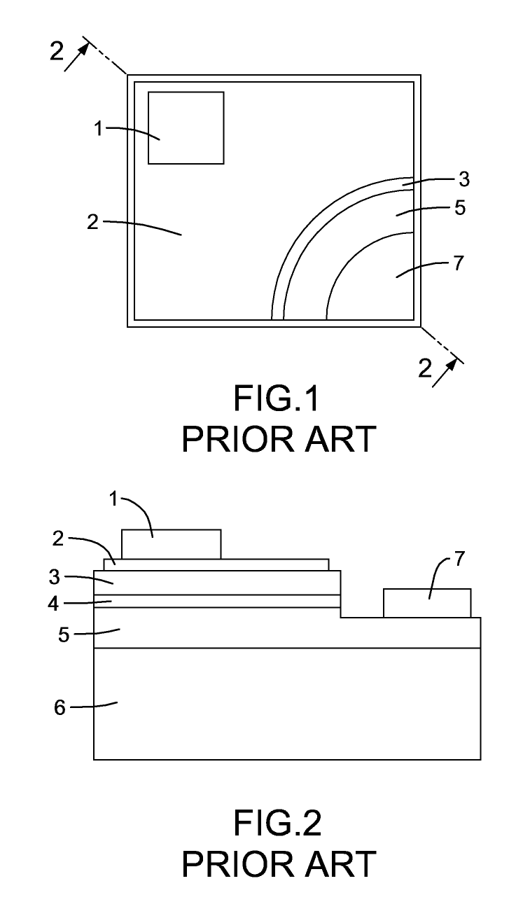

### DETAILED DESCRIPTION OF THE PREFERRED EMBODIMENT

### I. FIRST EMBODIMENT

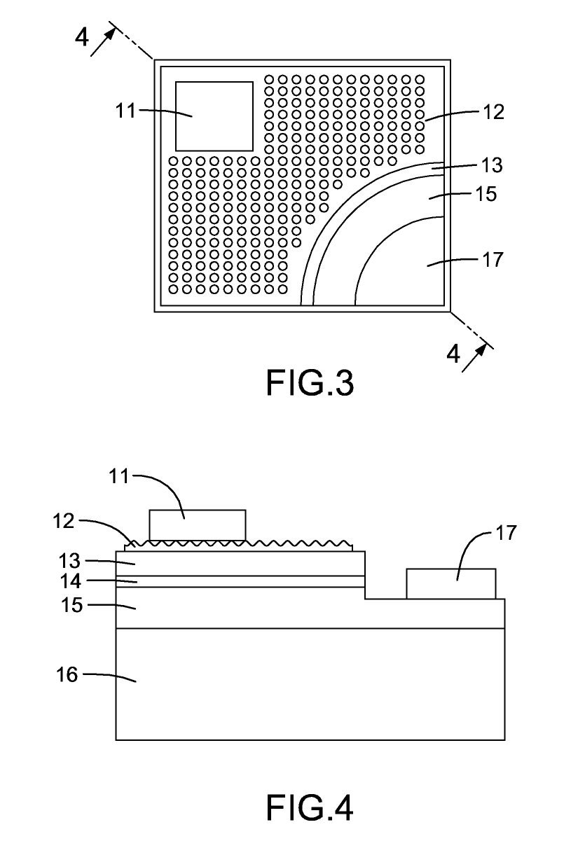

With reference to FIGS. 3 and 4, a plan view of an LED device in accordance with the present invention is shown in FIG. 3 and a cross sectional view of the LED device is FIG. 4 that is taken from a line 4-4 as indicated in FIG. 3. The LED device comprises a substrate (16), an N-type semiconductor layer (15) formed on the substrate (16), a light-emitting layer (14) on the N-type semiconductor layer (15), a P-type semiconductor layer (13) on the light-emitting layer (14), a transparent electrode layer (12) on the P-type semiconductor layer (13), an anode (11) formed on the transparent electrode layer (12) and a cathode (17) formed on the N-type semiconductor layer (15). A top surface of the transparent electrode layer (12) is formed to have multiple micro concave-convex structures.

The material of the N-type semiconductor layer (15), the light-emitting layer (14) and the P-type semiconductor layer (13) may be gallium nitride (GaN). The material of the transparent electrode layer (12) may be indium tin oxide (ITO), zinc oxide (ZnO) or other transparent conductive material. The thickness range of the transparent electrode layer (12) is from 0.2 to 0.8 micrometers.

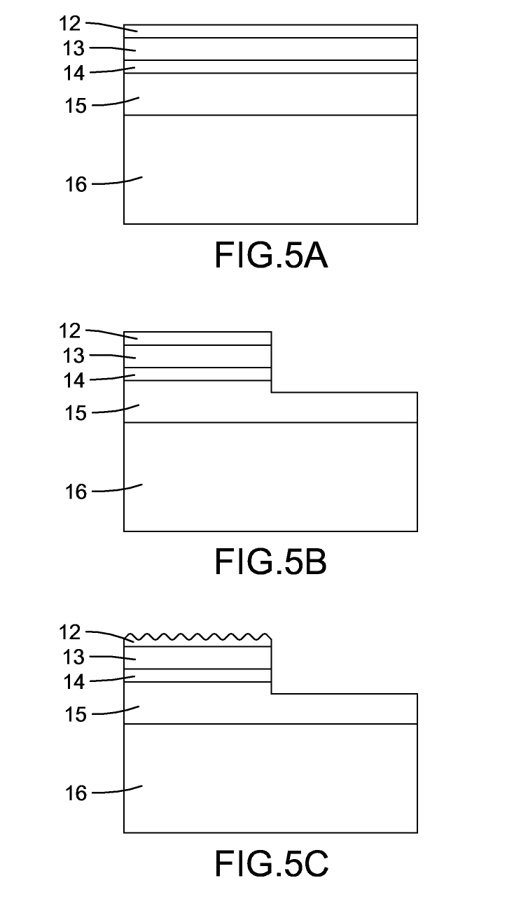

With reference to FIGS. 5A to 5C, the manufacturing processes of the first embodiment of the LED device in accordance with the present invention are shown. On the substrate (16) the N-type semiconductor layer (15), the light-emitting layer (14) and the P-type semiconductor layer (13) are sequentially formed by depositing processes. Then, the transparent electrode layer (12) is formed on the P-type semiconductor layer (13) as shown in FIG. 5A. For example, the transparent electrode layer (13) with a thickness between 0.2 to 0.8 micrometers can be pasted on the P-type semiconductor layer (13). A photolithography process is then used to pattern and etch parts of the transparent electrode layer (12), the P-type semiconductor layer (13), the light-emitting layer (14) and the N-type semiconductor layer (15), remaining parts of the transparent electrode layer (12), the P-type semiconductor layer (13), the light-emitting layer (14) on a part of the N-type semiconductor layer (15), as shown in FIG. 5B. The etching process may be an inductively coupled reactive ion etching process using chlorine, boron trichlorideor or methane. After the photolithography process, a wet etching process using roughening etchant is applied to form a roughened surface with multiple micro concave-convex structures, as shown in FIG. 5C. For example, when the roughening etchant is indirectly heated through water to about 70 to 80 degrees centigrade, the LED structure as shown in FIG. 5B can be dipped in the roughening etchant for 2 to 3 minutes. The roughening etchant is an acid solution composed of sulfuric acid, inhibitor, surfactant and deionized water. Cleaning and drying processes are then applied to the etched structure to form the micro concave-convex structures on the surface of the transparent electrode layer (12). Finally, the anode (11) and the cathode (17) are respectively formed on the transparent electrode layer (12) and the exposed N-type semiconductor layer (15).

Since the surface of the transparent electrode layer (12) has multiple micro concave-convex structures, the incident angle of the light transmitting from the transparent electrode layer (12) to packaging material of the LED is changed, wherein the incident angles of most light will be larger than a threshold angle of total reflection to increase the light-emitting efficiency of the LED device. When a current of 350 milli-ampere drives the LED device in accordance with the present invention, the light-emitting efficiency increases 20 to 30 percentages than conventional LED.

### II. SECOND EMBODIMENT

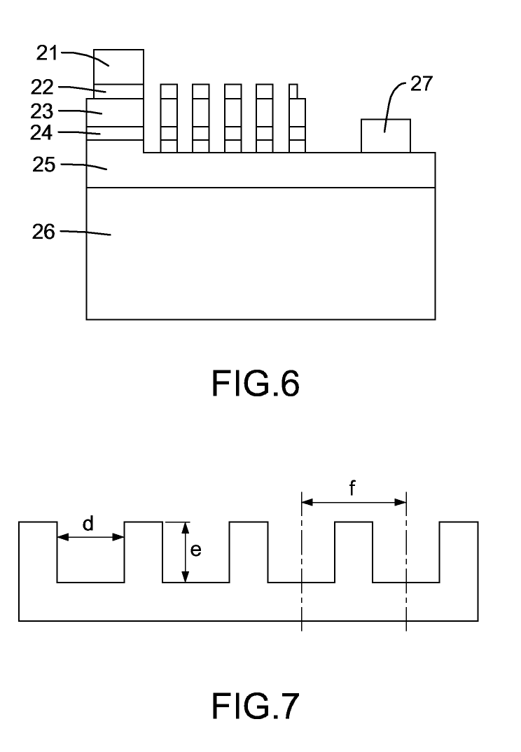

With reference to FIG. 6, a cross section view of a second embodiment of the LED device in accordance with the present inventions is shown, and FIG. 7 is a schematic view showing a part of the enlarged micro concave-convex structure. The LED device comprises a substrate (26), an N-type semiconductor layer (25) formed on the substrate (26), a light-emitting layer (24) on the N-type semiconductor layer (25), a P-type semiconductor layer (23) on the light-emitting layer (24), a transparent electrode layer (22) on the P-type semiconductor layer (23), an anode (21) formed on the transparent electrode layer (22) and a cathode (27) formed on the N-type semiconductor layer (25). The LED device further has multiple holes defined through the transparent electrode layer (22), the P-type semiconductor layer (23), the light-emitting layer (24) and a part of the N-type semiconductor layer (25). The holes may be distributed regularly or irregularly on the transparent electrode layer (22). The shape of the holes can be circular, oval, rectangular or triangular. The holes shown on FIG. 7 are circular holes with a pitch (f) of 2 to 8 micrometers, a depth (e) of 1 to 2 micrometers and a diameter (d) of 0.2 to 4 micrometers. The pitch is measured from a center of one to a center of another adjacent hole.

The material of the N-type semiconductor layer (25), the light-emitting layer (24) and the P-type semiconductor layer (23) may be gallium nitride (GaN). The material of the transparent electrode layer (22) may be indium tin oxide (ITO), zinc oxide (ZnO) or other transparent conductive material. The thickness range of the transparent electrode layer (22) is from 0.2 to 0.8 micrometers.

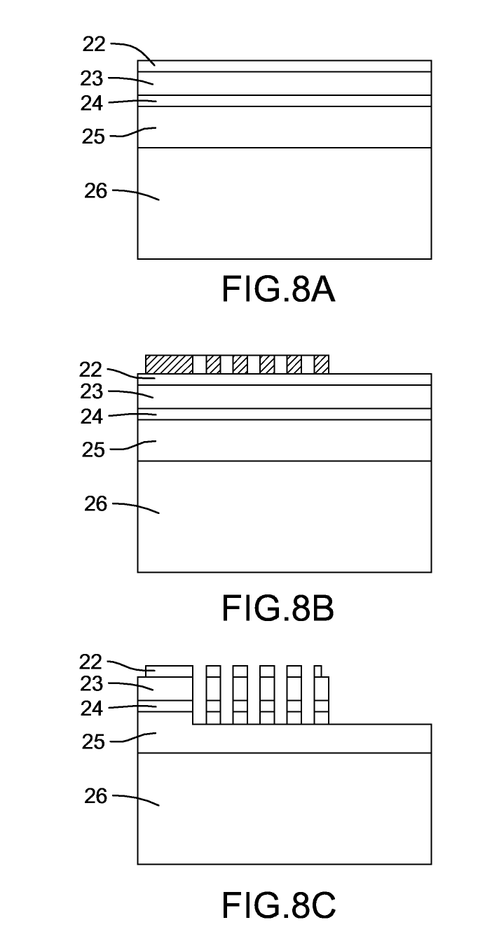

With reference to FIGS. 8A to 8C, the manufacturing processes of the second embodiment of the LED device in accordance with the present invention are shown. On the substrate (26) the N-type semiconductor layer (25), the light-emitting layer (24) and the P-type semiconductor layer (23) are sequentially formed by depositing processes. Then, the transparent electrode layer (22) is formed on the P-type semiconductor layer (23) as shown in FIG. 8A. For example, the transparent electrode layer (13) with a thickness between 0.2 to 0.8 micrometers can be pasted on the P-type semiconductor layer (23). A photoresist layer is coated on the transparent electrode layer (22). A photolithography process, for example using a nano-engineering optical system, is then used to pattern the multiple holes, as shown in FIG. 8B. Using the patterned photoresist layer as a protection layer, a dry etching process is applied to etch parts of the transparent electrode layer (22), the P-type semiconductor layer (23), the light-emitting layer (24) and the N-type semiconductor layer (25), forming the multiple holes that extend from the transparent electrode layer (22) to the N-type semiconductor layer (25). The photoresist layer is then removed from the transparent electrode layer (22) as shown in FIG. 8C. Finally, the anode (21) and the cathode (27) are respectively formed on the transparent electrode layer (22) and the exposed N-type semiconductor layer (25) to form the LED device as shown in FIG. 6. The dry etching process may be an inductively coupled reactive ion etching process.

Since the LED device has multiple holes extending from the transparent electrode layer (22) to the N-type semiconductor layer (25), the top surface of the transparent electrode layer (22) is equivalent to have multiple micro concave-convex structures. Further, that structure will increase the total light emitting area, and the photonics crystal effect will be formed. More and more light will be emitted from the emitting surface area. Therefore, the incident angle of the light transmitting from the transparent electrode layer (12) to the packaging material of the LED is changed, wherein the incident angles of most light will be larger than a threshold angle of total reflection to increase the light-emitting efficiency of the LED device.

### III. THIRD EMBODIMENT

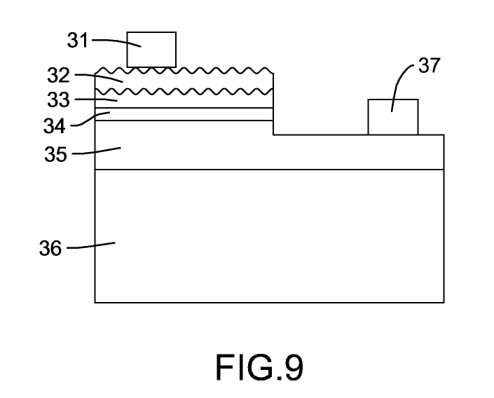

With reference to FIG. 9, a cross section view of a third embodiment of the LED device in accordance with the present inventions is shown. The LED device comprises a substrate (36), an N-type semiconductor layer (35) formed on the substrate (36), a light-emitting layer (34) on the N-type semiconductor layer (35), a P-type semiconductor layer (33) on the light-emitting layer (34), a transparent electrode layer (32) on the P-type semiconductor layer (33), an anode (31) formed on the transparent electrode layer (32) and a cathode (37) formed on the N-type semiconductor layer (35). Both the top surface and bottom surface of the transparent electrode layer (32) have the micro concave-convex structures.

The material of the N-type semiconductor layer (35), the light-emitting layer (34) and the P-type semiconductor layer (33) may be gallium nitride (GaN). The material of the transparent electrode layer (32) may be indium tin oxide (ITO), zinc oxide (ZnO) or other transparent conductive material. The thickness range of the transparent electrode layer (32) is from 0.2 to 0.8 micrometers.

The manufacturing processes for the third embodiment is basically the same as that of the first embodiment, but differs in that a dry or wet etching process is applied to etch the top surface of the P-type semiconductor layer (33) to form multiple micro concave-convex structures before forming of the transparent electrode layer (32). Therefore, when the transparent electrode layer (32) is formed on the P-type semiconductor layer (33), the bottom surface of the transparent electrode layer (32) accordingly has the micro concave-convex structures.

Since the top surface and the bottom surface of the transparent electrode layer (32) has multiple micro concave-convex structures, the incident angle of the light transmitting from the transparent electrode layer (32) to packaging material of the LED is changed, wherein the incident angles of most light will be larger than a threshold angle of total reflection to increase the light-emitting efficiency of the LED device.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for manufacturing an LED device comprising:
sequentially depositing an N-type semiconductor layer, a light-emitting layer and a P-type semiconductor layer on a substrate;
forming a transparent electrode layer on the P-type semiconductor layer;
pattering and etching parts of the transparent electrode layer, the P-type semiconductor layer, the light-emitting layer and the N-type semiconductor layer with an photolithography process; and
wet etching the transparent electrode layer with roughening etchant to form multiple micro concave-convex structures on the transparent electrode layer.

2. The method as claimed in claim 1, the roughening etchant is an acid solution composed of sulfuric acid, inhibitor, surfactant and deionized water.

3. The method as claimed in claim 1, wherein a dry or wet etching process is applied to a top surface of the P-type semiconductor layer before forming the transparent electrode layer on the P-type semiconductor layer to form multiple micro concave-convex structures on the top surface of the P-type semiconductor layer.

4. The method as claimed in claim 1, wherein the transparent electrode layer has a thickness of about 0.2 to about 0.8 micrometers.

5. A method for manufacturing an LED device comprising:
sequentially depositing an N-type semiconductor layer, a light-emitting layer and a P-type semiconductor layer on a substrate;
forming a transparent electrode layer on the P-type semiconductor layer;
coating a photoresist layer on the transparent electrode layer and pattering the transparent electrode layer with photolithography processes to define patterns of multiple holes;
using the photoresist layer as a protection layer and etching parts of the transparent electrode layer, the P-type semiconductor layer, the light-emitting layer and the N-type semiconductor layer with a dry etching process to form the multiple holes that extend from the transparent electrode layer to the N-type semiconductor layer; and
removing the photoresist layer from the transparent electrode layer.

6. The method as claimed in claim 5, wherein the dry etching process is an inductively coupled reactive ion etching process.

7. The method as claimed in claim 5, wherein a pitch between adjacent two of the multiple holes is in a range of 2 to 8 micrometers, and each of the multiple holes has a depth of 1 to 2 micrometers and a diameter of 0.2 to 4 micrometers.
